(19) United States
(12) Patent Application Publication
(10) Pub. No.: US 2023/0052788 A1
(43) Pub. Date: Feb. 16, 2023

(54) Software-Defined Synthesizable Testbench

(71) Applicant: Intel Corporation, Santa Clara, CA (US)

(72) Inventor: Sheran Rashel Cardoza, Scarborough (CA)

(21) Appl. No.: 17/970,557

(22) Filed: Oct. 20, 2022

Related U.S. Application Data
(60) Provisional application No. 63/409,648, filed on Sep. 23, 2022.

(51) Int. Cl. G01R 31/319; G01R 31/3185

(52) U.S. Cl. CPC G01R 31/31917; G01R 31/31908; G01R 31/318536

(57) ABSTRACT

Integrated circuit devices, systems, and circuitry are provided to perform signal tests on a device under test. One such integrated circuit device may include memory having instructions to generate a number of test streams to send to a device under test and a testbench processor. The testbench processor may generate the test streams based on the instructions using thread execution circuitry that switches context based on context identifiers corresponding to respective test streams.

### CROSS-REFERENCE TO RELATED APPLICATIONS

This application claims priority to U.S. Provisional Application No. 63/409,648 filed Sep. 23, 2022, entitled “Software-Defined Synthesizable Testbench,” which is incorporated herein by reference in its entirety for all purposes.

### BACKGROUND

This disclosure relates to integrated circuitry to efficiently generate software-defined test streams to use on a device under test.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Before they may be operated, many integrated circuits undergo a variety of tests. These include tests while the integrated circuit is being designed, after the integrated circuit has been manufactured, or after the integrated circuit is in use in a product. Depending on the functionality provided by the integrated circuit, different tests may be performed. As the bandwidth or throughput supported by many integrated circuits has grown, generating test signals to sufficiently test these integrated circuits may be untenable using existing solutions. Moreover, as new vulnerabilities of integrated circuit devices are discovered, such as row-hammer vulnerabilities, new test signals may be desired to more fully test the integrated circuit.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device;

FIG. 2 is a block diagram of the integrated circuit device of FIG. 1;

FIG. 3 is a block diagram of the integrated circuit device of FIG. 1 programmed with a testbench soft processor to test a second integrated circuit device;

FIG. 4 is a block diagram of a software construct of the testbench soft processor;

FIG. 5 is a block diagram of an implementation of the testbench soft processor on the integrated circuit device of FIG. 1;

FIG. 6 is a block diagram of thread execution circuitry of the testbench soft processor;

FIG. 7 is a block diagram of a distributed instruction graph (DIG) of instructions that may be executed by the testbench soft processor; and

FIG. 8 is a block diagram of a data processing system that may incorporate the integrated circuit with the testbench soft processor.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

To test a variety of different integrated circuit devices under test (DUT), a testbench processor is provided. The testbench processor may allow a software programmer to generate code that can run on the testbench processor to test a variety of different conditions on an integrated circuit device under test. For example, the testbench processor may be used to generate a variety of traffic scenarios, including sequential patterns, random patterns, pseudo-random patterns, row-hammer address patterns, or new test patterns that may be of interest in the future. The testbench processor may generate read-heavy traffic interleaved with writes, generate different burst lengths (e.g., alternate between two burst lengths). Moreover, because the testbench processor may avoid using nested finite state machines, intertwined control signals may be avoided and the testbench processor may be relatively easily extended by writing new code to run on the testbench processor. The testbench processor may be used to test a variety of different integrated circuit devices under test—including different FPGA system designs even on the same integrated circuit device as the testbench processor—without additional, sometimes complex tasks such as customizing register transfer language (RTL) of test logic circuitry for different devices under test. In this way, testbench processor may be used to test a wide variety of integrated circuit devices, including but not limited to DDR3/4 memory, QDR-IV memory, DDR-T memory, and high-bandwidth memory (HBM).

To do so, the testbench processor may include a traffic generator that stitched using pipelined RTL blocks designed to be latency-insensitive and generate a high (e.g., 90%, 95%, 100%) throughput stream. The RTL blocks include control units to fetch and stream instructions, and ALU generators to stream complex patterns. Various drivers are then integrated along with clocking and reset circuitry and remote access paths (e.g., Joint Test Action Group (JTAG) access paths) to build the testbench processor. Because the testbench processor may be instantiated in programmable logic circuitry (e.g., FPGA circuitry), the testbench processor may be described as a software-driven synthesizable testbench. The reusable RTL blocks allow easily building hardware testbenches for new IPs, which is software-driven and may have a comparatively high maximum frequency (Fmax). Because the testbench processor is software-driven, the traffic pattern generated by the testbench processor may be customizable via application programming interfaces of suitable programming languages (e.g., Python APIs).

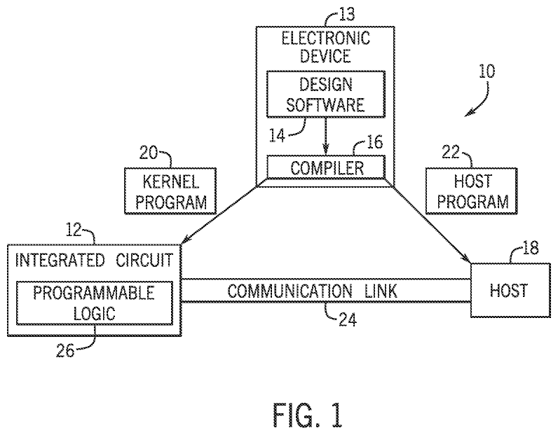

With the foregoing in mind, FIG. 1 illustrates a block diagram of a system 10 that may be used in configuring an integrated circuit 12 to include a testbench processor. A designer may desire to implement testbench functionality on the integrated circuit 12 (e.g., a programmable logic device such as a field-programmable gate array (FPGA) or an application-specific integrated circuit (ASIC) that includes programmable logic circuitry). The integrated circuit 12 may include a single integrated circuit, multiple integrated circuits in a package, or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit 12 without specific knowledge of low-level hardware description languages (e.g., Verilog, very high speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit 12.

In a configuration mode of the integrated circuit 12, a designer may use an electronic device 13 (e.g., a computer) to implement high-level designs (e.g., a system user design) using design software 14, such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit 12. The host 18 may receive a host program 22 that may be implemented by the kernel programs 20. To implement the host program 22, the host 18 may communicate instructions from the host program 22 to the integrated circuit 12 via a communications link 24 that may be, for example, direct memory access (DMA) communications or peripheral component interconnect express (PCIe) communications. In some embodiments, the kernel programs 20 and the host 18 may enable configuration of programmable logic 26 on the integrated circuit 12. The programmable logic 26 may include circuitry and/or other logic elements and may be configurable to implement arithmetic operations, such as addition and multiplication.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

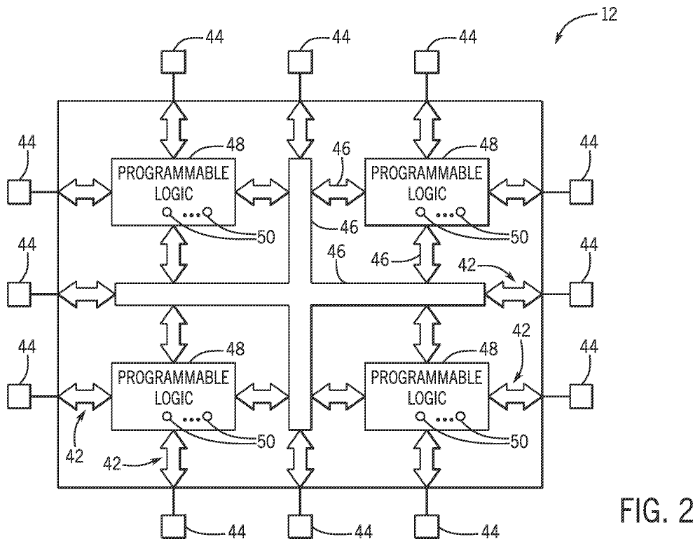

Turning now to a more detailed discussion of the integrated circuit 12, FIG. 2 is a block diagram of an example of the integrated circuit 12 as a programmable logic device, such as a field-programmable gate array (FPGA). Further, it should be understood that the integrated circuit 12 may be any other suitable type of programmable logic device (e.g., an ASIC and/or application-specific standard product). The integrated circuit 12 may have input/output circuitry 42 for driving signals off of the device (e.g., integrated circuit 12) and for receiving signals from other devices via input/output pins 44. Interconnection resources 46, such as global and local vertical and horizontal conductive lines and buses, and/or configuration resources (e.g., hardwired couplings, logical couplings not implemented by user logic), may be used to route signals on integrated circuit 12. Additionally, interconnection resources 46 may include fixed interconnects (conductive lines) and programmable interconnects (i.e., programmable connections between respective fixed interconnects). Programmable logic 26 may include combinational and sequential logic circuitry. For example, programmable logic 26 may include look-up tables, registers, and multiplexers. In various embodiments, the programmable logic 26 may be configurable to perform a custom logic function. The programmable interconnects associated with interconnection resources may be considered to be a part of programmable logic 26.

Programmable logic devices, such as the integrated circuit 12, may include programmable elements 50 with the programmable logic 26. For example, as discussed above, a designer (e.g., a customer) may program (e.g., configure) or reprogram (e.g., reconfigure, partially reconfigure) the programmable logic 26 to perform one or more desired functions. By way of example, some programmable logic devices may be programmed or reprogrammed by configuring programmable elements 50 using mask programming arrangements that is performed during semiconductor manufacturing. Other programmable logic devices are configurable after semiconductor fabrication operations have been completed, such as by using electrical programming or laser programming to program programmable elements 50. In general, programmable elements 50 may be based on any suitable programmable technology, such as fuses, antifuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming (i.e., configuration), configuration data is loaded into the memory cells using input/output pins 44 and input/output circuitry 42. In one embodiment, the memory cells may be implemented as random-access-memory (RAM) cells. The use of memory cells based on RAM technology is described herein is intended to be only one example. Further, since these RAM cells are loaded with configuration data during programming, they are sometimes referred to as configuration RAM cells (CRAM). These memory cells may each provide a corresponding static control output signal that controls the state of an associated logic component in programmable logic 26. For instance, in some embodiments, the output signals may be applied to the gates of metal-oxide-semiconductor (MOS) transistors within the programmable logic 26.

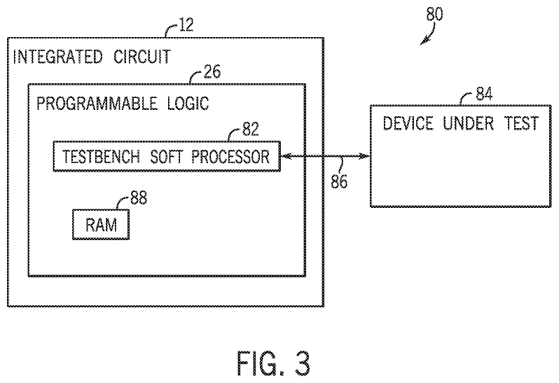

Keeping the discussion of FIG. 1 and FIG. 2 in mind, a user (e.g., designer) may use the design software 14 to configure the programmable logic 26 of the integrated circuit 12 (e.g., with a user system design). In particular, the designer may specify in a high-level program that mathematical operations, such as addition and multiplication, be performed. The compiler 16 may convert the high-level program into a lower-level description that is used to configure the programmable logic 26. For example, the programmable logic 26 of the integrated circuit 12 may be configured with a testbench processor, as shown in FIG. 3.

FIG. 3 illustrates a test system 80 in which the programmable logic 26 of the integrated circuit 12 includes a testbench processor 82. The testbench processor 82 may generate test signals to test any suitable device under test (DUT) 84 via communication wires 86. Random access memory (RAM) 88 may store instructions and data, as well as the test results of tests carried out by the testbench processor 82. The RAM 88 may be any suitable memory accessible to the integrated circuit 12. In the example of FIG. 3, the RAM 88 is shown as on-chip memory of the programmable logic circuitry 26 (e.g., an M20k of an FPGA by Intel Corporation). However, the RAM 88 may be wholly or partly separate from the programmable logic 26, off-chip, or off-package.

The device under test (DUT) 84 may be any suitable integrated circuit device or system. For example, the device under test (DUT) 84 may be a memory device (e.g., DDR3/4 memory, QDR-IV memory, DDR-T memory, high-bandwidth memory (HBM)), networking circuitry, or a processor, to provide a few examples. The device under test (DUT) 84 may be a circuit component on the same die as the integrated circuit 12, a different die in the same package, or a different package. Indeed, additionally or alternatively, the device under test (DUT) 84 may be circuitry of a system design configured into the programmable logic circuitry 26 or another component of the integrated circuit 12 (e.g., memory of the integrated circuit 12).

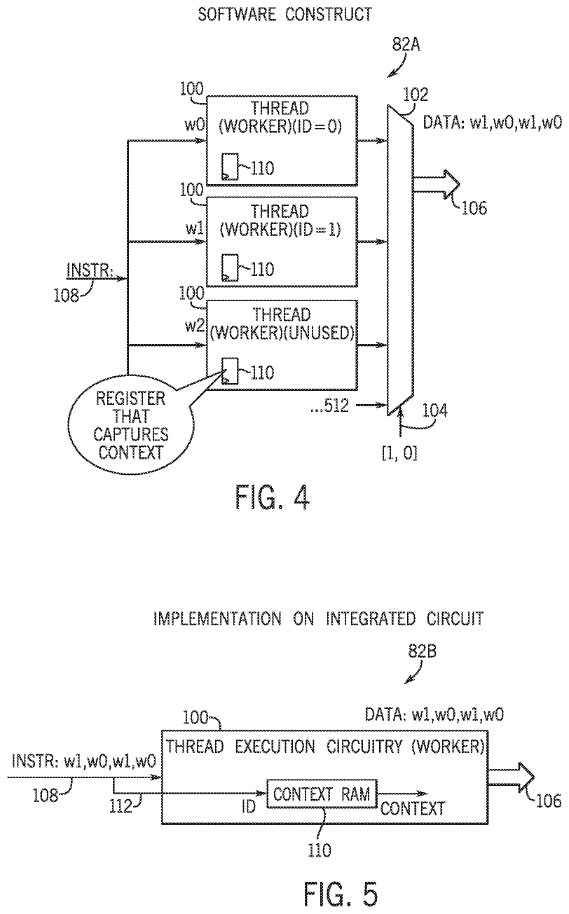

The testbench processor 82 may be programmed by a developer to carry out a variety of test patterns. For example, the testbench processor 82 may be used to send test signals on an Advanced eXtensible Interface (AXI) bus or peripheral component interconnect express (PCIe) bus. The AXI bus protocol allows multiple traffic streams interleaved on a single bus. Each traffic stream is tagged with a unique ID, allowing the DUT to return responses out-of-order across the traffic streams. A current version of AXI allows 512 IDs, so the testbench processor 82 may be used to generate 512 unique traffic streams. Future versions of AXI or other protocols may generate even more unique traffic streams. One approach, visualized in a software construct of a testbench processor 82A shown in FIG. 4, would be to synthesize 512 independent workers 100, which may also be referred to as threads or traffic generators. The workers 100 may output test signals that are multiplexed by a multiplexer 102 based on a context identifier, referred to in this disclosure as a worker ID 104, to generate test streams 106 onto the same AXI bus. The workers 100 may receive instructions 108 with their specific worker ID and may include context memory 110 (e.g., shown here as a separate context register for each worker).

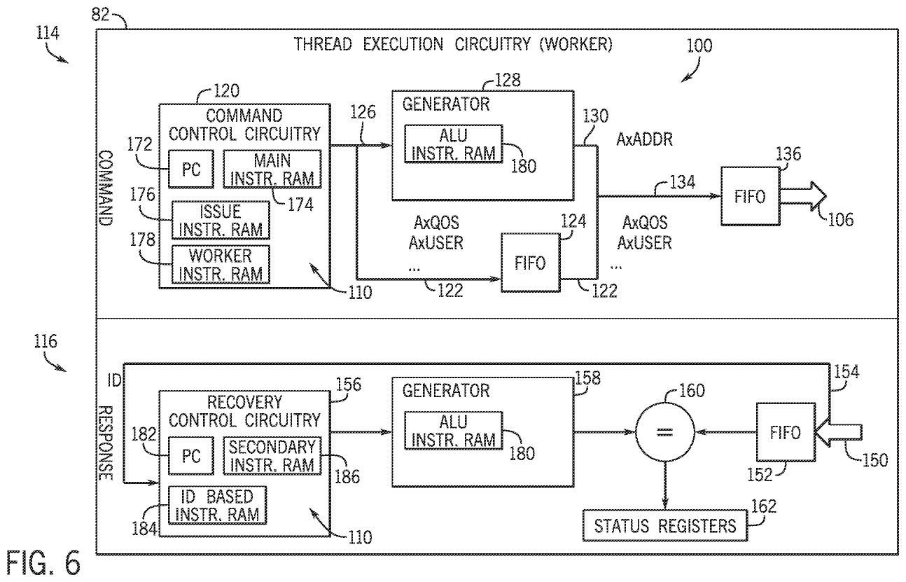

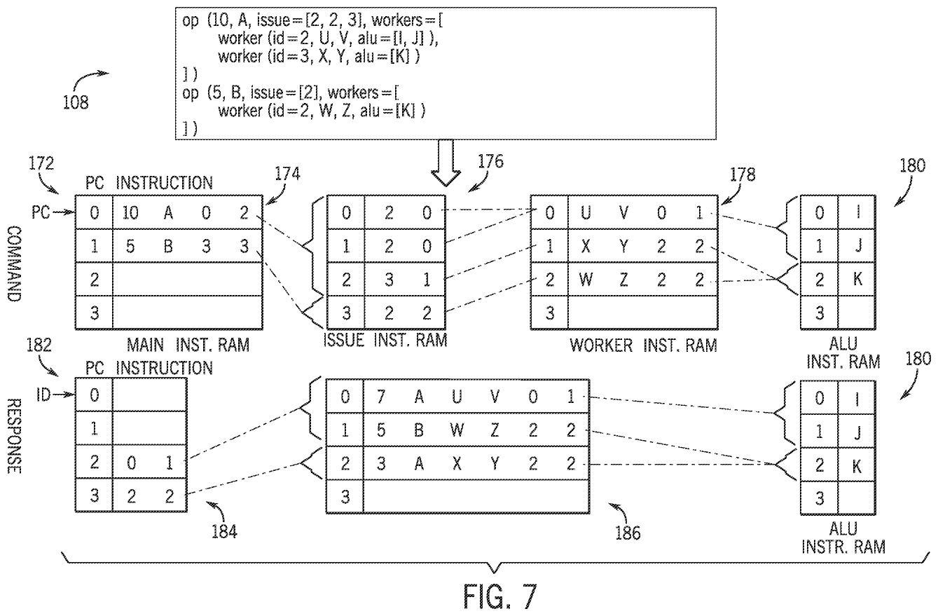

If the software construct of the testbench processor 82A shown in FIG. 4 were implemented in exactly this form on the integrated circuit 12 (e.g., as a configuration program of the programmable logic circuitry), this could introduce significant challenges, such as large area consumption and timing closure issues. As such, an integrated circuit implementation of a testbench processor 82B shown in FIG. 5 may include a worker 100 that may operate as a single “traffic generator” that context-switches between 512 worker IDs. The integrated circuit implementation of a testbench processor 82B shown in FIG. 5 may similarly use instructions 108 for which a context identifier, here shown as a worker ID 112, may be identified and used by context memory 110 to fetch a context of that worker ID 112. The context memory 110 may be saved and fetched from on-chip RAM in a single clock cycle based on the worker ID 112. There may be as few as a single instance of the worker 100 in a testbench processor 82. Rather than perform hardware-based context switching using saving and fetching context from a centralized register file or RAM, the approach used by the testbench processor 82 may include several disjunct on-chip RAMs spread across different pipeline stages that asynchronously context-switch, as will be discussed further below with reference to FIGS. 6 and 7.

FIG. 6 provides an illustration of components of the worker 100, which may also be referred to as thread execution circuitry. The worker 100 may include command circuitry 114 and response circuitry 116. The command circuitry 114 of the worker 100 may include control circuitry for commands 120, which may provide static data values 122 to a first-in-first-out memory (FIFO) 124 and instructions 126 to generator circuitry 128. The generator circuitry 128 may include any suitable circuitry to generate dynamic test signals 130, such as memory addresses and/or commands, that may be combined with the static data values 122 from the FIFO 124 to produce test signals 134 that enter another FIFO 136. The FIFO 136 may output the test signals 134 as test streams 106 over a bus (e.g., an AXI bus, a PCIe bus) to a device under test (DUT) (not shown in FIG. 6).

The device under test (DUT) (not shown in FIG. 6) may receive the test streams 106, perform operations, and provide a response. As a result, the worker 106 may receive a test result stream 150 from the device under test (DUT) (not shown in FIG. 6), which may be loaded into a FIFO 152. Since response signals of the test result stream 150 may identify the context ID for that response, the context ID may be provided (e.g., as signal 154) to control circuitry for recovery 156. This is because, while the test signals 134 of the test streams 106 may be provided in a particular worker order, the responses in the test result stream 150 may return in a different worker order as the device under test handles different signals with different order (e.g., due to different latencies or priorities). The control circuitry for recovery 156 may provide instructions to another instance of a generator 158, which may use the instructions to recreate the expected response. Analysis circuitry 160 may compare the expected response (e.g., expected data, expected metadata) from the generator 158 with the actual response (e.g., received data, received metadata) stored in the FIFO 152 and save the results into status registers 162. This may allow the testbench processor 82 to identify errors in communication (e.g., errors in the bus over which test signals or response signals traverse, errors in the behavior of the device under test). The status registers 162 may also store actual data or metadata.

The testbench processor 82 may avoid significant overhead using an instruction set architecture (ISA) referred to as Distributed Instruction Graph (DIG). The DIG ISA allows for very efficient instruction memory usage by distributing instructions across several different memories. These memories are shown in FIG. 6 in the control for command circuitry 120 as a program counter (PC) 172, a main instruction RAM 174, an issue instruction RAM 176, and a worker instruction RAM 178; in the generator circuitry 128 and generator logic circuitry 158 as an arithmetic logic unit (ALU) (e.g., processing element) instruction RAM; and in the control circuitry for recovery 156 as a program counter 182, an ID-based instruction RAM 184, and a secondary instruction RAM 186. One manner in which the DIG ISA may efficiently distribute instructions through these memories is shown in FIG. 7.

The DIG ISA is helpful because a software traffic pattern can define a single traffic stream (for a single ID) or 512 traffic streams (for 512 IDs). Using a very long instruction word (VLIW) ISA instead of DIG would involve allocating for the largest instruction size of ˜100,000 bits, which would consume 3,125 32-bit wide 20 kB memories, which is infeasible. Distributed Instruction Graph (DIG) may be used to split the variable-length portions of the instruction into separate RAMs and split the time-multiplexed portions across separate rows. While this introduces an overhead to store pointers, RAM usage is proportional to code complexity (˜200 bits per traffic stream which consumes 6 32-bit wide 20 kB memories). RAM usage can further be reduced by removing replicas and editing pointers.

Any suitable programming language may be used to define an AXI traffic pattern. One example of code to define an AXI traffic pattern as instructions 108 in the Python API is provided in FIG. 7. A compiler (e.g., the compiler 16 of FIG. 1) may translate the code into DIG microcode by distributing various aspects to the different memories 174, 176, 178, 180, 182, 184, and 186. In the example of FIG. 7, the code used is:

```
op(10, A, issue=[2, 2, 3], workers=[
  worker(id=2, U, V, alu=[I, J]),
  worker(id=3, X, Y, alu=[K])
])
op(5, B, issue=[2], workers=[
  worker(id=2, W, Z, alu=[K])
])
```

Where “Op” corresponds to any suitable operation (e.g., read, write), “issue” corresponds to the order of worker IDs that are to execute ALU instructions, and “worker” corresponds to the instructions to be carried out by different worker IDs. Metadata “A” and “B” correspond to any suitable metadata relating to the operation, and metadata “U”, “V”, “X”, “Y”, “W”, and “Z” correspond to any suitable metadata relating to executing a particular worker instruction. The ALU instructions “I”, “J”, and “K” correspond to any suitable ALU instructions that may be executed by the generator circuitry 128. From a different perspective, equivalent RISC pseudocode for an AXI traffic generator may take the format:

```
for i in iterations:
  for worker in workers:
    for alu_op in alu_ops:
      execute_instr(worker.id, alu_op)
```

In essence, the DIG ISA implements a fixed loop structure without the use of branch instructions. In the example of FIG. 7, operations may be distributed to the main instruction RAM 174 and based on count to be used by the program counter (PC) 172. In the example of FIG. 7, the first operation is to be performed 10 times using metadata “A” and the second operation is to be performed 5 times using metadata “B.” The main instruction RAM 174 includes pointers to the issue instruction RAM 176. The issue instruction RAM 176 includes entries that list the particular worker ID for each issue and a pointer to corresponding entries in the worker instruction RAM 178. In this example, the issue instruction RAM 176 includes entries for three issue instructions for the first operation, the first two for worker “2” and the third for worker “3,” and one entry for an issue instruction for the second operation for worker “2.” The worker instruction RAM 178 includes entries with metadata corresponding with the worker instruction and pointers to a particular ALU instruction in the ALU instruction RAM 180. In the example of FIG. 7, the first entry of the worker instruction RAM 178 lists metadata “U” and “V” and points to two ALU instructions of the ALU instruction RAM 180 corresponding to ALU instructions “I” and “J.” The second and third entries of the worker instruction RAM 178 list metadata “X” and “Y”, and “W” and “Z”, respectively, and point to the third entry of the ALU instruction RAM 180, listing ALU instruction “K.”

For responses, the compiler may distribute aspects of the instructions based on worker ID rather than operation order, since responses from a device under test (DUT) to the test signals may return in a different order than the test signals. Thus, in the example of FIG. 7, the instruction ID-based instruction RAM 184 may use a program counter (PC) that selects the worker ID found in the worker ID from the latest response from a device under test. The instruction ID-based instruction RAM 184 may include pointers to the secondary instruction RAM 186, which lists the number of times each instruction is to occur per operation. For instance, the first operation is carried out by worker “2” a total of 7 times, since out of the total of 10 times the operation is carried out, it is carried out in this issue order: worker “2”, “2”, “3”, “2”, “2”, “3”, “2”, “2”, “3”, “2.” The secondary instruction RAM 186 also includes the metadata corresponding to the operation carried out by each respective worker and pointers to the ALU instruction RAM 180 for the ALU instructions that are carried out.

The high efficiency of Distributed Instruction Graph (DIG) thus may allow 100% throughput instruction stream, and consequently a 100% throughput data stream for AXI protocol test streams. This is an ideal property for test traffic generation. The testbench processor 82 of this disclosure may also be used to test non-memory protocols such as content-addressable memory (CAM), PHY-Lite, and Mobile Industry Processor Interface (MIPI). Additionally, the remote access path may leverage PCIe or JTAG for faster access speeds. Moreover, the software may execute on-chip either in a hardened processor system (HPS) processor or in a soft processor (e.g., a NIOS processor configured onto an FPGA), rather than remotely on a host PC.

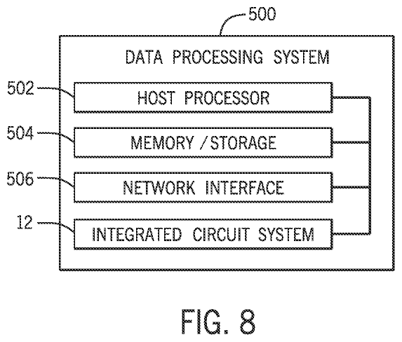

The integrated circuit system 12 may be a component included in a data processing system, such as a data processing system 500, shown in FIG. 8. The data processing system 500 may include the integrated circuit system 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). The integrated circuit 12 may be used to perform a built-in self-test (BIST) of any of the components of the data processing system 500 or test other electronic components that may be in communication with the data processing system 500. The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit system 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

### Example Embodiment 1

An integrated circuit device comprising:

memory comprising instructions to generate a plurality of test streams to send to a device under test; and

a testbench processor to generate the plurality of test streams based on the instructions using thread execution circuitry that switches context based on context identifiers corresponding to respective test streams of the plurality of test streams.

### Example Embodiment 2

The integrated circuit device of example embodiment 1, wherein the memory comprises a plurality of memories over which components of the instructions are distributed to implement a fixed loop structure without branch instructions.

### Example Embodiment 3

The integrated circuit device of example embodiment 1, wherein the memory comprises at least three memories over which components of the instructions are distributed.

### Example Embodiment 4

The integrated circuit device of example embodiment 1, wherein the memory comprises:

an arithmetic logic unit (ALU) instruction memory to store entries comprising ALU instructions of operations to be executed in one or more ALUs of the testbench processor;

a worker instruction memory to store entries per context identifier and operation and pointers to the ALU instruction memory;

an issue instruction memory to store entries per issue order of context identifiers and pointers to the worker instruction memory; and

a main instruction memory to store entries per operation comprising pointers to the issue instruction memory.

### Example Embodiment 5

The integrated circuit device of example embodiment 4, wherein respective entries of the main instruction memory comprise:

an indication of a number of times to repeat the operation corresponding to that entry of the main instruction memory; and

metadata corresponding to the operation corresponding to that entry of the main instruction memory.

### Example Embodiment 6

The integrated circuit device of example embodiment 1, wherein the testbench processor comprises a single instance of the thread execution circuitry.

### Example Embodiment 7

The integrated circuit device of example embodiment 1, wherein the testbench processor comprises a command region to generate the plurality of test streams and a response region to analyze responses from the device under test in response to the test streams.

### Example Embodiment 8

The integrated circuit device of example embodiment 7, wherein the response region is to analyze responses by context.

### Example Embodiment 9

The integrated circuit of example embodiment 1, wherein the plurality of test streams are to send to the device under test via an Advanced eXtensible Interface (AXI) bus.

### Example Embodiment 10

The integrated circuit of example embodiment 1, wherein the testbench processor is formed at least in part in field programmable gate array (FPGA) programmable logic circuitry.

### Example Embodiment 11

A system comprising:

a device under test to receive a plurality of test streams associated with respective identifiers and respond with respective response signals associated with the respective identifiers; and

an integrated circuit to generate the plurality of test streams using an instance of thread execution circuitry that switches context based on the identifier.

### Example Embodiment 12

The system of example embodiment 11, wherein the plurality of test streams conform to the Advanced eXtensible Interface (AXI) protocol.

### Example Embodiment 13

The system of example embodiment 11, wherein the plurality of test streams conform to a non-memory protocol.

### EXAMPLE EMBODIMENT 14

The system of example embodiment 11, wherein the integrated circuit comprises a plurality of disjunct memories storing instructions to cause the integrated circuit to generate the plurality of test streams, wherein the instructions are distributed over the plurality of memories to implement a fixed loop structure without branch instructions.

### Example Embodiment 15

The system of example embodiment 11, wherein the plurality of disjunct memories comprise:

an arithmetic logic unit (ALU) instruction memory to store entries comprising ALU instructions of operations to be executed in one or more ALUs of the integrated circuit;

a worker instruction memory to store entries per context identifier and operation and pointers to the ALU instruction memory;

an issue instruction memory to store entries per issue order of context identifiers and pointers to the worker instruction memory; and

a main instruction memory to store entries per operation comprising pointers to the issue instruction memory.

### Example Embodiment 16

The system of example embodiment 11, wherein the integrated circuit comprises a command region to generate the plurality of test streams and a response region to analyze responses from the device under test in response to the test streams.

### Example Embodiment 17

The system of example embodiment 16, wherein the response region is to analyze responses by context.

### Example Embodiment 18

The system of example embodiment 11, wherein the device under test comprises DDR3 memory, DDR4 memory, QDR-IV memory, DDR-T memory, or high-bandwidth memory (HBM).

### Example Embodiment 19

Thread execution circuitry comprising:

command control circuitry to issue command instructions associated with a context identifier;

first generator circuitry to generate a dynamic component of a test stream associated with the context identifier based on the command instructions;

output circuitry to send the test stream to a device under test;

input circuitry to receive a response from the device under test based on the test stream, wherein the device under test comprises the context identifier;

recovery control circuitry to issue recovery instructions based on the context identifier of the response;

second generator circuitry to generate an expected response from the device under test based on the test stream;

analysis circuitry to compare the response from the device under test to the expected response.

### Example Embodiment 20

The thread execution circuitry of example embodiment 19, wherein the command control circuitry comprises static data or metadata and wherein the static data or metadata is combined with the dynamic component of the test stream before the test stream is sent to the device under test.

### Example Embodiment 21

The circuitry of example embodiment 19, wherein the circuitry is formed at least in part in field programmable gate array (FPGA) programmable logic circuitry.

What is claimed is:

1. An integrated circuit device comprising:
memory comprising instructions to generate a plurality of test streams to send to a device under test; and
a testbench processor to generate the plurality of test streams based on the instructions using thread execution circuitry that switches context based on context identifiers corresponding to respective test streams of the plurality of test streams.

2. The integrated circuit device of claim 1, wherein the memory comprises a plurality of memories over which components of the instructions are distributed to implement a fixed loop structure without branch instructions.

3. The integrated circuit device of claim 1, wherein the memory comprises at least three memories over which components of the instructions are distributed.

4. The integrated circuit device of claim 1, wherein the memory comprises:
an arithmetic logic unit (ALU) instruction memory to store entries comprising ALU instructions of operations to be executed in one or more ALUs of the testbench processor;
a worker instruction memory to store entries per context identifier and operation and pointers to the ALU instruction memory;
an issue instruction memory to store entries per issue order of context identifiers and pointers to the worker instruction memory; and
a main instruction memory to store entries per operation comprising pointers to the issue instruction memory.

5. The integrated circuit device of claim 4, wherein respective entries of the main instruction memory comprise:
an indication of a number of times to repeat the operation corresponding to that entry of the main instruction memory; and
metadata corresponding to the operation corresponding to that entry of the main instruction memory.

6. The integrated circuit device of claim 1, wherein the testbench processor comprises a single instance of the thread execution circuitry.

7. The integrated circuit device of claim 1, wherein the testbench processor comprises a command region to generate the plurality of test streams and a response region to analyze responses from the device under test in response to the test streams.

8. The integrated circuit device of claim 7, wherein the response region is to analyze responses by context.

9. The integrated circuit of claim 1, wherein the plurality of test streams are to send to the device under test via an Advanced eXtensible Interface (AXI) bus.

10. The integrated circuit of claim 1, wherein the testbench processor is formed at least in part in field programmable gate array (FPGA) programmable logic circuitry.

11. A system comprising:
a device under test to receive a plurality of test streams associated with respective identifiers and respond with respective response signals associated with the respective identifiers; and
an integrated circuit to generate the plurality of test streams using an instance of thread execution circuitry that switches context based on the identifier.

12. The system of claim 11, wherein the plurality of test streams conform to the Advanced eXtensible Interface (AXI) protocol.

13. The system of claim 11, wherein the plurality of test streams conform to a non-memory protocol.

14. The system of claim 11, wherein the integrated circuit comprises a plurality of disjunct memories storing instructions to cause the integrated circuit to generate the plurality of test streams, wherein the instructions are distributed over the plurality of memories to implement a fixed loop structure without branch instructions.

15. The system of claim 11, wherein the plurality of disjunct memories comprise:
an arithmetic logic unit (ALU) instruction memory to store entries comprising ALU instructions of operations to be executed in one or more ALUs of the integrated circuit;
a worker instruction memory to store entries per context identifier and operation and pointers to the ALU instruction memory;
an issue instruction memory to store entries per issue order of context identifiers and pointers to the worker instruction memory; and
a main instruction memory to store entries per operation comprising pointers to the issue instruction memory.

16. The system of claim 11, wherein the integrated circuit comprises a command region to generate the plurality of test streams and a response region to analyze responses from the device under test in response to the test streams.

17. The system of claim 16, wherein the response region is to analyze responses by context.

18. The system of claim 11, wherein the device under test comprises DDR3 memory, DDR4 memory, QDR-IV memory, DDR-T memory, or high-bandwidth memory (HBM).

19. Thread execution circuitry comprising:
command control circuitry to issue command instructions associated with a context identifier;
first generator circuitry to generate a dynamic component of a test stream associated with the context identifier based on the command instructions;
output circuitry to send the test stream to a device under test;
input circuitry to receive a response from the device under test based on the test stream, wherein the device under test comprises the context identifier;
recovery control circuitry to issue recovery instructions based on the context identifier of the response;
second generator circuitry to generate an expected response from the device under test based on the test stream;
analysis circuitry to compare the response from the device under test to the expected response.

20. The thread execution circuitry of claim 19, wherein the command control circuitry comprises static data or metadata and wherein the static data or metadata is combined with the dynamic component of the test stream before the test stream is sent to the device under test.

21. The circuitry of claim 19, wherein the circuitry is formed at least in part in field programmable gate array (FPGA) programmable logic circuitry.
